(19) United States
(12) Patent Application Publication
(10) Pub. No.: US 2025/0357737 A1
(43) Pub. Date: Nov. 20, 2025

(54) WIRE HARNESS

(71) Applicant: SUMITOMO WIRING SYSTEMS, LTD., Yokkaichi-shi, Mie (JP)

(72) Inventor: Junya SUZUKI, Yokkaichi-shi (JP)

(73) Assignee: SUMITOMO WIRING SYSTEMS, LTD., Yokkaichi-shi, Mie (JP)

(21) Appl. No.: 18/872,510

(22) PCT Filed: Jun. 6, 2023
(86) PCT No.: PCT/JP2023/020942

§ 371 Date: Dec. 6, 2024

(30) Foreign Application Priority Data
Jun. 15, 2022 (JP) 2022-096644

(51) Int. Cl. H02G 3/04; B60R 16/02; H01B 7/00

(52) U.S. Cl. CPC H02G 3/0406; B60R 16/0215; H01B 7/0045; H02G 3/0487

(57) ABSTRACT

A wire harness for high voltage, at least a portion of which is configured to be located inside a vehicle compartment separated by a body of a vehicle from an outside of the vehicle, the wire harness including: an electric wire; a metallic shield that covers the electric wire; a resin case that is configured to be disposed inside the vehicle compartment, wherein the resin case has a U-shaped transverse cross section and an opening that is configured to be on a side opposite to the body, and the electric wire and the shield are housed in the resin case; and a metallic cover that has a U-shaped transverse cross section, wherein the metallic cover covers the opening of the resin case and is configured to be open on a side facing the body.

### BACKGROUND

The present disclosure relates to a wire harness.

Conventionally, for example, hybrid cars and electric cars include a wire harness for high voltage. Such a wire harness may be disposed so as to pass outside a body of a vehicle (e.g., underneath the floor) (see JP 2019-32933A, for example). When the wire harness is disposed in such a manner, an impact of a magnetic field generated by a large electric current on a passenger is suppressed due to, for example, the body being interposed between the wire harness and the passenger.

### SUMMARY

However, when a wire harness for high voltage as described above is disposed so as to pass inside a vehicle compartment (i.e., on the floor), there is a concern that a magnetic field generated by a large electric current may have an impact on a passenger unless some measure is taken.

An exemplary aspect of the invention provides a wire harness capable of suppressing an impact of a magnetic field with a simple configuration.

A wire harness of the present disclosure is a wire harness for high voltage, at least a portion of which is configured to be located inside a vehicle compartment separated by a body of a vehicle from an outside of the vehicle, the wire harness including: an electric wire; a metallic shield that covers the electric wire; a resin case that is configured to be disposed inside the vehicle compartment and has an opening and in which the electric wire and shield are housed; and a metallic cover that covers the opening of the resin case, wherein the resin case includes a holding portion capable of holding the metallic member.

With the wire harness of the present disclosure, it is possible to suppress the impact of a magnetic field with a simple configuration.

### BRIEF DESCRIPTION OF THE DRAWINGS

FIG. 1 is a schematic configuration diagram illustrating a wire harness of an embodiment.

FIG. 2 is a perspective view illustrating a portion of the wire harness of the embodiment.

FIG. 3 is an exploded perspective view illustrating a portion of the wire harness of the embodiment.

FIG. 4 is a cross-sectional view taken along line 4-4 in FIG. 2.

### DETAILED DESCRIPTION OF EMBODIMENTS

### Description of Embodiments of the Present Disclosure

First, aspects of the present disclosure will be listed and described.

[1] A wire harness of the present disclosure is a wire harness for high voltage, at least a portion of which is located inside a vehicle compartment separated by a body of a vehicle from an outside of the vehicle, the wire harness including: an electric wire member that includes an electric wire and a metallic shielding member covering the electric wire; a resin case that is disposed inside the vehicle compartment and has an opening and in which the electric wire member is housed; and a metallic member covering the opening of the resin case, wherein the resin case includes a holding portion capable of holding the metallic member.

With this configuration, the metallic shielding member covering the electric wire suppresses the radiation of an electromagnetic wave such as electromagnetic noise. Since the metallic member covers the opening of the resin case that is disposed inside the vehicle compartment and in which the electric wire member is housed, the impact of a magnetic field generated by a large electric current on a passenger is suppressed. Also, the metallic member covers the opening of the resin case and thus functions as a physical cover for preventing the dislodgement of the electric wire member from the resin case, thus making it possible to simplify the configuration compared to, for example, a configuration in which a separate resin cover for covering the opening of the resin case is provided. In addition, the metallic member is held by the holding portion of the resin case, thus making it possible to reduce the size compared to, for example, a configuration in which the metallic member is provided with a mounting foot or the like and is fastened and fixed to the body or the like using a bolt.

[2] In [1] above, the metallic member may be held by the holding portion while being spaced apart from the body.

With this configuration, the metallic member is held by the holding portion while being spaced apart from the body, and therefore, the metallic member is prevented, for example, from being subjected to the application of force irrespective of production errors and the like. That is to say, with a configuration in which, for example, the metallic member is held by the holding portion of the resin case while abutting against the body, if the dimensions of the metallic member vary due to production errors and the like, there is a risk that force may remain to be applied to the metallic member between the holding portion and the body. However, with the configuration above, such a situation can be avoided.

[3] In [1] or [2] above, the metallic member may have a U-shaped transverse cross section and be open on a side facing the body.

With this configuration, the metallic member has a U-shaped transverse cross section and is open on the side facing the body, and therefore, the body and the metallic member can surround the entire outer periphery of the electric wire member. Accordingly, an impact of a magnetic field generated by a large electric current on a passenger is favorably suppressed.

[4] In any one of [1] to [3] above, the resin case may have a U-shaped transverse cross section and have the opening on a side opposite to the body.

With this configuration, the resin case has a U-shaped transverse cross section and has the opening on the side opposite to the body with the opening being covered by the metallic member, and therefore, the metallic member is interposed between a passenger inside the vehicle compartment and the electric wire member. Accordingly, the impact of a magnetic field generated by a large electric current on a passenger is suppressed.

[5] In any one of [1] to [4] above, the shielding member may be formed using a braided member, and the metallic member may be formed using a metallic plate.

With this configuration, the shielding member is formed using a braided member and the metallic member is formed using a metallic plate, thus making it possible to make their configurations suitable. That is to say, the shielding member is formed using a braided member, thus making it possible to favorably suppress the radiation of an electromagnetic wave such as electromagnetic noise. The metallic member is formed using a metallic plate, thus making it possible to favorably suppress the impact of a magnetic field generated by a large electric current on a passenger.

[6] In any one of [1] to [5] above, the electric wire may be a first electric wire for high potential, and the wire harness may further include a second electric wire for low potential that is housed in the resin case together with the electric wire member without being covered by the shielding member.

With this configuration, the second electric wire for low potential paired with the first electric wire for high potential is housed in the resin case together with the electric wire member without being covered by the shielding member. Accordingly, it is possible to avoid needless use of the shielding member for the second electric wire for low potential, and in addition, the first electric wire and the second electric wire can be favorably routed using the resin case in common.

[7] In any one of [1] to [6] above, the shielding member may include a grounding portion.

With this configuration, the shielding member includes the grounding portion, thus making it possible to favorably suppress the radiation of an electromagnetic wave such as electromagnetic noise.

[8] In any one of [1] to [7] above, the resin case may include a fixation portion to be fixed to the body.

With this configuration, the resin case includes the fixation portion to be fixed to the body and can thus be easily fixed to the body.

### Details of Embodiments of the Present Disclosure

The following describes specific examples of a wire harness of the present disclosure with reference to the drawings. A portion of the configuration may be exaggerated or simplified for illustrative purposes in the diagrams. In addition, the ratios between the dimensions of portions shown in the diagrams may be different from each other. Note that the present disclosure is not limited to these examples and is defined by the scope of the appended claims, and all changes that fall within the same essential spirit as the scope of the claims are intended to be included therein. The terms “parallel” and “orthogonal” as used herein encompass not only “precisely parallel” and “precisely orthogonal” but also “substantially orthogonal”, as long as the functions and effects of these embodiments are exhibited. In addition, the terms “circle” and “arc” as used herein encompass not only “precise circle” and “precise arc” but also “substantially a circular shape” and “substantially an arc shape”, as long as the functions and effects of these embodiments are exhibited.

### Overall Configuration of Wire Harness 10

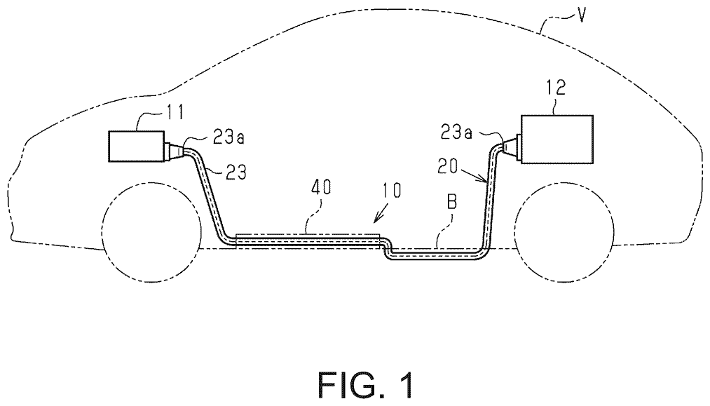

A wire harness 10 shown in FIG. 1 electrically connects two or three or more electric apparatuses. The wire harness 10 can conduct electricity with a high voltage, and electrically connects, for example, an inverter 11 that is provided in a front portion of a vehicle V such as a hybrid car or electric car, and a high-voltage battery 12 that is provided on a rear side relative to the inverter 11 in the vehicle V.

The inverter 11 is connected to a wheel drive motor (not illustrated) that is a power source for the traveling of the vehicle. The inverter 11 generates AC power from DC power provided by the high voltage battery 12, and supplies the AC power to the motor. The high voltage battery 12 can supply, for example, a voltage of several hundred volts.

At least a portion of the wire harness 10 is located inside a vehicle compartment separated by a body B of the vehicle V from the outside of the vehicle V. The wire harness 10 of this embodiment is disposed so as to pass outside the body B (e.g., underneath the floor) in the rear portion of the vehicle V and pass inside the body B (i.e., on the floor) from the center of the vehicle V to the front portion. That is to say, the wire harness 10 is routed so as to pass on the floor (i.e., inside the body B) in a portion corresponding to the driver's seat and the passenger seat.

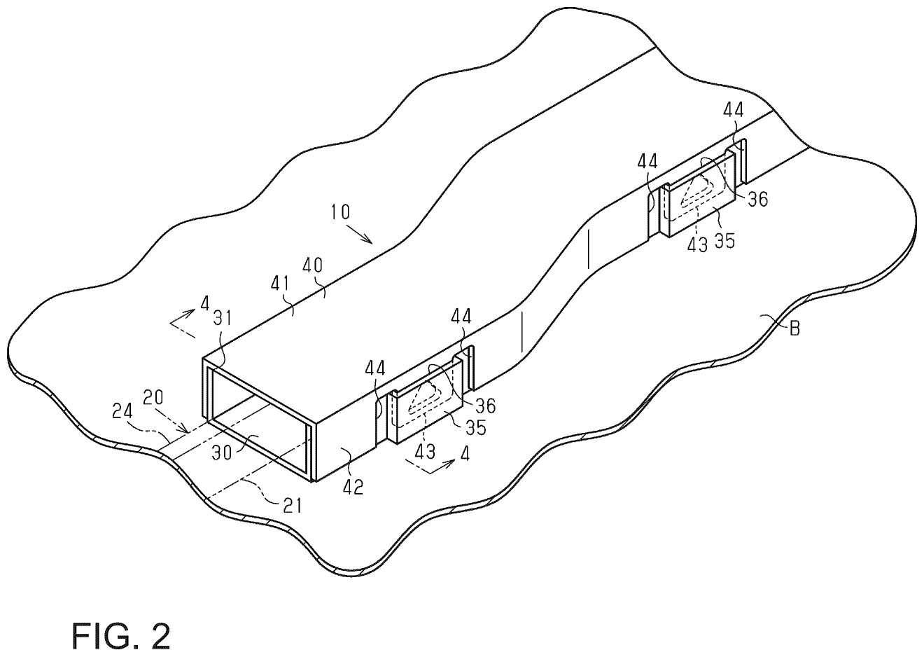

As shown in FIGS. 2 to 4, the wire harness 10 includes an electric wire group 20 for electrically connecting the electric apparatuses, a resin case 30, and a metallic member 40 (metallic cover).

### Configuration of Electric Wire Group 20

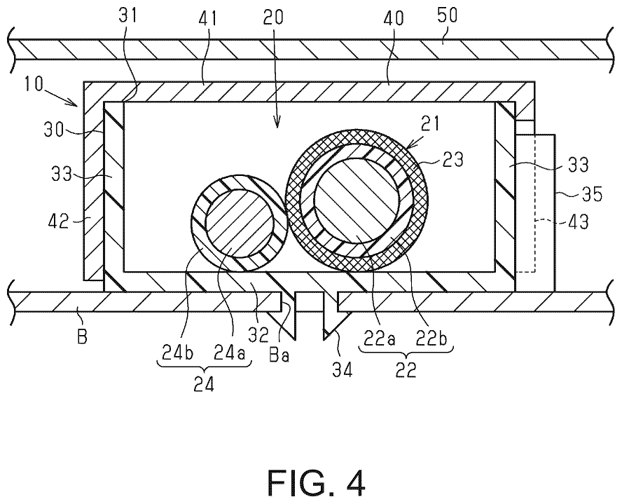

As shown in FIG. 4, the electric wire group 20 includes an electric wire member 21. The electric wire member 21 includes a first electric wire 22 serving as an electric wire for high potential and a metallic shielding member 23 (metallic shield) covering the first electric wire 22. The first electric wire 22 includes a core wire 22a and an insulating coating 22b covering the outer periphery of the core wire 22a. Examples of the core wire 22a include a stranded wire formed by twisting a plurality of metallic strands together, and a single-core wire. The insulating coating 22b is made of, for example, an insulating material such as a synthetic resin. The shielding member 23 is constituted of a braided member formed by braiding a plurality of metallic strands into a tubular shape. That is to say, the electric wire member 21 is a so-called shielded electric wire.

Also, the electric wire group 20 includes a second electric wire 24 for low potential. The second electric wire 24 includes a core wire 24a and an insulating coating 24b covering the outer periphery of the core wire 24a. Examples of the core wire 24a include a stranded wire formed by twisting a plurality of metallic strands together, and a single-core wire. The insulating coating 24b is made of, for example, an insulating material such as a synthetic resin. The diameter of the second electric wire 24 is smaller than that of the first electric wire 22. The core wire 22a of the first electric wire 22 for high potential is connected to the positive terminal of the high-voltage battery 12, and the core wire 24a of the second electric wire 24 for low potential is connected to the negative terminal of the high voltage battery 12.

As shown in FIG. 1, the shielding member 23 includes grounding portions 23a. The grounding portions 23a are provided at both end portions of the shielding member 23 and are grounded by, for example, being electrically connected to a metallic case or the body B via a connector or the like.

### Configuration of Resin Case 30

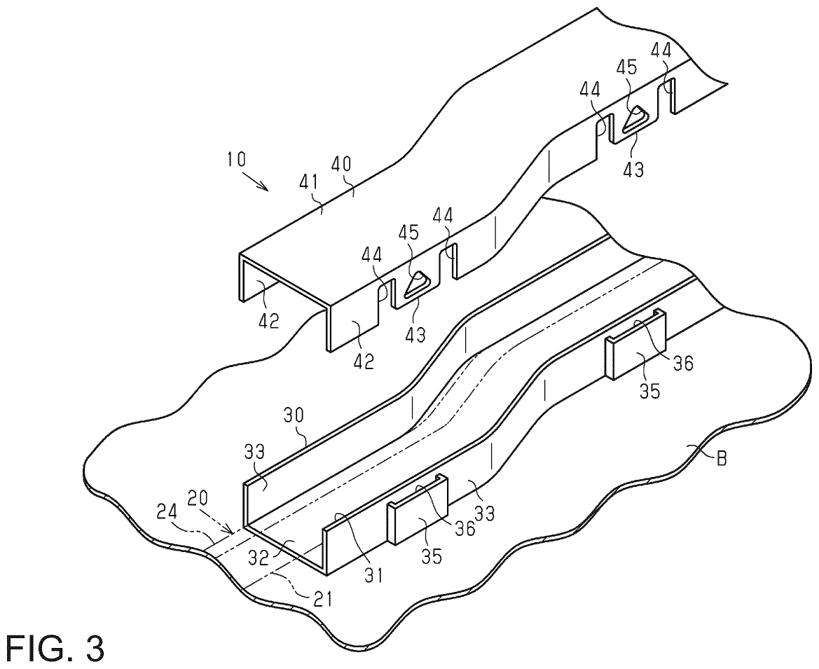

As shown in FIGS. 3 and 4, the resin case 30 has a U-shaped transverse cross section and has an opening 31 on a side opposite to the body B. The resin case 30 of this embodiment has an elongated shape extending in the front-rear direction of the vehicle V in order to house the electric wire group 20 routed along the front-rear direction of the vehicle V.

Specifically, as shown in FIG. 4, the resin case 30 includes a bottom portion 32 facing the body B, and side wall portions 33 that are bent and extend from the bottom portion 32. The bottom portion 32 is provided with latching portions 34 serving as fixation portions. The latching portions 34 are provided at a plurality of positions on the resin case 30 that are aligned in the longitudinal direction. When being fitted to a fixation hole Ba provided in the body B, the latching portions 34 are engaged therewith in a dislodgement direction and is thus fixed to the body B.

As shown in FIG. 3, holding portions 35 are provided on the side wall portion 33. The holding portions 35 are provided at a plurality of positions on the resin case 30 that are aligned in the longitudinal direction. Although FIG. 3 is illustrated as if the holding portions 35 are provided on only one of the side wall portions 33 of the resin case 30, the holding portions 35 may also be provided on the other side wall portion 33. Each of the holding portions 35 protrudes outward from the side wall portion 33 and has an insertion portion 36 that is open on a side opposite to the body B. In addition, the holding portion 35 includes a hook (not illustrated) thereinside.

### Configuration of Metallic Member 40

As shown in FIGS. 3 and 4, the metallic member 40 has a U-shaped transverse cross section and is open on a side facing the body B. The metallic member 40 is formed using a metallic plate. That is to say, the metallic member 40 is formed by punching or bending a metallic plate. The metallic member 40 is attached so as to cover the opening 31 of the resin case 30.

Specifically, the metallic member 40 includes a top portion 41 that covers the opening 31 of the resin case 30, and side portions 42 that are bent and extend from the top portion 41, and cover the side wall portions 33 of the resin case 30.

As shown in FIG. 3, holding pieces 43 to be held by the holding portions 35 of the resin case 30 are provided on the side portion 42. The holding pieces 43 are provided at plurality of positions on the metallic member 40 that correspond to the holding portions 35 and are aligned in the longitudinal direction. A pair of notches 44 extending from the leading end of the side portion 42 toward the base end thereof are formed, and thereby the holding piece 43 can be inserted into the insertion portion 36. A holding hole 45 is provided in the holding piece 43. When the holding piece 43 is inserted into the insertion portion 36 of the holding portion 35, the hook (not illustrated) of the holding portion 35 is engaged with the holding hole 45, and thereby the holding piece 43 is held in the holding portion 35.

As shown in FIG. 4, the side portions 42 have such a length that the side portions 42 do not abut against the body B in a state in which the metallic member 40 is held by the holding portions 35 of the resin case 30. Thus, the metallic member 40 is held by the holding portions 35 while being spaced apart from the body B.

For example, as shown in FIG. 4, a floor carpet 50 is disposed over the metallic member 40.

The following describes the functions of the embodiment above.

The electric wire group 20 passing inside the body B (i.e., on the floor) is covered by the resin case 30 and the metallic member 40. Accordingly, even when, for example, a passenger treads on the wire harness 10 via the floor carpet 50 thereover, the electric wire group 20 is prevented from being subjected to the application of force and undergoing deformation.

Next, the following describes the effects of the embodiment above.

(1) The metallic shielding member 23 covering the first electric wire 22 suppresses the radiation of an electromagnetic wave such as electromagnetic noise. Since the metallic member 40 covers the opening 31 of the resin case 30 that is disposed inside the vehicle compartment and in which the electric wire member 21 is housed, the impact of a magnetic field generated by a large electric current flowing through the first electric wire 22 of the electric wire member 21 on a passenger is suppressed. Also, the metallic member 40 covers the opening 31 of the resin case 30 and thus functions as a physical cover for preventing the dislodgement of the electric wire member 21 from the resin case 30. Accordingly, it is possible to simplify the configuration compared to, for example, a configuration in which a separate resin cover for covering the opening 31 of the resin case 30 is provided. In addition, the metallic member 40 is held by the holding portions 35 of the resin case 30, thus making it possible to reduce the size compared to, for example, a configuration in which the metallic member 40 is provided with a mounting foot or the like and is fastened and fixed to the body or the like using a bolt.

(2) The metallic member 40 is held by the holding portions 35 while being spaced apart from the body B, and therefore, the metallic member 40 is prevented, for example, from being subjected to the application of force irrespective of production errors and the like. That is to say, with a configuration in which, for example, the metallic member 40 is held by the holding portions 35 of the resin case 30 while abutting against the body B, if the dimensions of the metallic member 40 vary due to production errors and the like, there is a risk that force may remain to be applied to the metallic member 40 between the holding portions 35 and the body B. However, with the configuration above, such a situation can be avoided.

(3) The metallic member 40 has a U-shaped transverse cross section and is open on a side facing the body B. Therefore, the body B and the metallic member 40 can surround the entire outer periphery of the electric wire member 21. Accordingly, the impact of a magnetic field generated by a large electric current on a passenger is favorably suppressed.

(4) The resin case 30 has a U-shaped transverse cross section and has the opening 31 on a side opposite to the body B with the opening 31 being covered by the metallic member 40, and therefore, the metallic member 40 is interposed between a passenger inside the vehicle compartment and the electric wire member 21. Accordingly, the impact of a magnetic field generated by a large electric current on a passenger is suppressed.

(5) The shielding member 23 is formed using a braided member and the metallic member 40 is formed using a metallic plate, thus making it possible to make their configurations suitable. That is to say, the shielding member 23 is formed using a braided member, thus making it possible to favorably suppress the radiation of an electromagnetic wave such as electromagnetic noise. The metallic member 40 is formed using a metallic plate, thus making it possible to favorably suppress the impact of a magnetic field generated by a large electric current on a passenger.

(6) The second electric wire 24 for low potential paired with the first electric wire 22 for high potential is housed in the resin case 30 together with the electric wire member 21 without being covered by the shielding member 23. Accordingly, it is possible to avoid needless use of the shielding member 23 for the second electric wire 24 for low potential, and in addition, the electric wire member 21 that includes the first electric wire 22, and the second electric wire 24 can be favorably routed using the resin case 30 in common.

(7) The shielding member 23 includes the grounding portion 23a, thus making it possible to favorably suppress the radiation of an electromagnetic wave such as electromagnetic noise.

(8) The resin case 30 includes the latching portions 34 serving as the fixation portions to be fixed to the body B and can thus be easily fixed to the body B. In this embodiment, the latching portions 34 serve as the fixation portions, thus making it possible to fix the resin case 30 to the body B by merely fitting the latching portions 34.

This embodiment can be implemented with various modifications such as those described below. This embodiment and the following modified examples can be implemented in combination with each other as long as no technical contradiction arises.
Although the metallic member 40 is held by the holding portions 35 while being spaced apart from the body B in the embodiment above, there is no limitation to this configuration, and a configuration may also be employed in which a portion of the metallic member 40 abuts against the body B while the metallic member 40 is held by the holding portions 35 of the resin case 30.
Although the metallic member 40 has a U-shaped transverse cross section and is open on a side facing the body B in the embodiment above, there is no limitation to this configuration, and the transverse cross-sectional shape may be changed to another shape, or the metallic member 40 may be open on another side.
Although the resin case 30 has a U-shaped transverse cross section and is open on a side opposite to the body B in the embodiment above, there is no limitation to this configuration, and the transverse cross-sectional shape may be changed to another shape, or the resin case 30 may be open on another side.
Although the shielding member 23 is formed using a braided member and the metallic member 40 is formed using a metallic plate in the embodiment above, the materials of these members may be changed to other materials. For example, the shielding member 23 may be formed using a metallic foil or the like. Also, for example, a metallic member 40 may be changed to a cast product or the like constituted of portions with different thicknesses.
Although the second electric wire 24 for low potential paired with the first electric wire 22 for high potential is housed in the resin case 30 together with the electric wire member 21 without being covered by the shielding member 23 in the embodiment above, there is no limitation to this configuration, and the second electric wire 24 may also be covered by the shielding member. Of course, other electric wires such as a signal wire in addition to the first electric wire 22 and the second electric wire 24 may also be housed in the resin case 30.
Although the resin case 30 includes the latching portions 34 serving as the fixation portions to be fixed to the body B in the embodiment above, there is no limitation to this configuration, and another configuration may also be employed. For example, the fixation portion may be a mounting foot to be fastened to the body B using a bolt or the like. Also, a configuration may also be employed in which the resin case 30 includes no fixation portion to be fixed to the body B and is fixed to, for example, another member fixed to the body B.
Although the wire harness 10 electrically connects the inverter 11 and the high voltage battery 12 in the embodiment above, there is no limitation to this configuration, and the wire harness 10 may electrically connect other electric apparatuses.
Although the wire harness 10 compatible with the several hundred-volt high voltage battery 12 is embodied in the embodiment above, another high-voltage wire harness to which a voltage of 60 to 600 volts can be applied may be embodied.
The present disclosure encompasses the following aspect. For the purpose of not limiting but merely facilitating understanding, the reference numerals for the constituent elements of the embodiment above are used.

### Supplementary Note 1

A wire harness (10) for high voltage, at least a portion of which is located inside a vehicle compartment separated by a body (B) of a vehicle (V) from an outside of the vehicle (V), the wire harness (10) including:
an electric wire member (21) that includes an electric wire (22) and a metallic shielding member (23) covering the electric wire;
a resin case (30) that is disposed inside the vehicle compartment and in which the electric wire member (21) is housed; and
a metallic member (40) covering the resin case,
wherein the resin case (30) includes:
   a bottom portion (32) in contact with the body (B);
   a pair of side wall portions (33) that are bent and extend from the bottom portion; and
   an opening (31) located on a side opposite to the bottom portion (32),
the metallic member (40) includes:
   a top portion (41) covering the opening (31) of the resin case (30); and
   a pair of side portions (42) that are bent and extend from the top portion, and are in contact with an exterior surface of the pair of side wall portions (33) of the resin case (30), and
an entire outer periphery of the electric wire member (21) routed inside the vehicle compartment is surrounded by the body (B), the pair of side portions (42) of the metallic member (40), and the top portion (41) of the metallic member (40).

With this configuration, four sides around the electric wire member, namely the entire outer periphery of the electric wire member, routed inside the vehicle compartment are surrounded by metal, thus making it possible to suppress a magnetic field generated by an electric current flowing through the electric wire member.

The invention claimed is:

1. A wire harness for high voltage, at least a portion of which is configured to be located inside a vehicle compartment separated by a body of a vehicle from an outside of the vehicle, the wire harness comprising:
an electric wire;
a metallic shield that covers the electric wire;
a resin case that is configured to be disposed inside the vehicle compartment, wherein the resin case has a U-shaped transverse cross section and an opening that is configured to be on a side opposite to the body, and the electric wire and the shield are housed in the resin case; and
a metallic cover that has a U-shaped transverse cross section, wherein the metallic cover covers the opening of the resin case and is configured to be open on a side facing the body, wherein:
the resin case includes a holding portion that is provided on a side wall portion of the resin case and is configured to hold the metallic cover, and
the metallic cover includes a holding piece that is provided on a side of the metallic cover and is held by the holding portion.

2. The wire harness according to claim 1,
wherein the metallic cover is configured to be held by the holding portion while being spaced apart from the body.

3-4. (canceled)

5. The wire harness according to claim 1, wherein:
the shield is formed using a braided member, and
the metallic cover is formed using a metallic plate.

6. The wire harness according to claim 1, wherein:
the electric wire is a first electric wire for high potential, and
the wire harness further includes a second electric wire for low potential that is housed in the resin case together with the first electric wire and shield without being covered by the shield.

7. The wire harness according to claim 1,
wherein the shield includes a grounding portion.

8. The wire harness according to claim 1,
wherein the resin case includes a fixation portion that is configured to be fixed to the body.
